(19) United States
(12) Patent Application Publication
(10) Pub. No.: US 2026/0179321 A1
(43) Pub. Date: Jun. 25, 2026

(54) IMAGE AIDED CONSTRUCTION

(71) Applicant: Syracuse University, Syracuse, NY (US)

(72) Inventor: Edgar Amicar Rodriguez Lozano, Syracuse, NY (US)

(73) Assignee: Syracuse University, Syracuse, NY (US)

(21) Appl. No.: 19/430,901

(22) Filed: Dec. 23, 2025

Related U.S. Application Data
(60) Provisional application No. 63/737,866, filed on Dec. 23, 2024.

(51) Int. Cl. G06T 17/10

(52) U.S. Cl. CPC G06T 17/10

(57) ABSTRACT

A structure and a related method of assembling a structure made up of a plurality of individual building elements. A 2-dimensional continuous digital or analog image, such as a texture pattern, is mapped onto a 3-D model of the structure to be assembled. Portions of the continuous image are imprinted on a common facing surface of each of the individual building elements to serve as a visual guide for assembling the structure in conjunction with a unique naming code for each building element, the code being based on mapped coordinates of the 3-D model. A texture or other pattern can also be imbedded into a facing side of the assembled structure.

### CROSS REFERENCE TO RELATED APPLICATION

This application claims priority to U.S. application Ser. No. 63/737,866, filed Dec. 23, 2024, pursuant to relevant portions of 35 U.S.C. § 119 and 35 U.S.C. § 120. The above-noted application is herein incorporated by reference in its entirety.

### TECHNICAL FIELD

This application is generally directed to the field of construction, and more specifically to a method wherein portions of a continuous digital or analog image are imbedded into individual building elements along with a unique building or assembly code, in order to create a visual guide for the purpose of assembling a structure.

### BACKGROUND

Conventional construction methods heavily rely upon the use of detailed architectural drawings. These drawings can be extremely complex and difficult to follow for purposes of construction of a structure, requiring specialized knowledge and detailed instructions, as well as being highly labor, cost and time extensive.

Accordingly, there is a prevailing and recurrent need in the field to be able to simplify as well as improve conventional architectural and assembly techniques.

### BRIEF DESCRIPTION

Therefore and according to at least one aspect, there is provided a method for construction of a structure, the method comprising providing a plurality of individual construction elements, superimposing a continuous 2-D digital or analog image onto a 3-D model of a structure; imbedding a portion of the continuous digital or analog image onto at least one facing surface of each of the individual construction elements along with a unique building or assembly code, and reconstructing the continuous digital image by assembling the individual construction elements using the imbedded unique assembly code and continuous image portions, thereby creating the structure. According to an embodiment, the unique naming code is based on the mapped coordinates of the 3-D model having the superimposed digital or analog image.

The portions of the continuous digital or analog image can be deconstructed and therefore aligned with one another onto one facing side of each of the individual building elements, which can be for example, blocks or bricks. As to the unique building or assembly code, each of the building elements are also coded based on mapped coordinates of the continuous image as superimposed onto a 3-D model/rendition of the structure, and wherein the digital or analog image can be reconstructed in accordance with the herein described method as a visual guide for purposes of assembling the structure. Advantageously, the continuous digital or analog image serves not only as a visual construction guide, but further can provide an appealing, aesthetic feature of the assembled structure. As a result, the herein described method integrates both function and aesthetics, for example, the inclusion of one or more graphic designs into an assembled building structure.

The herein described method greatly simplifies conventional construction techniques, as providing a very intuitive and direct guide for accurately assembling a structure with a minimum of errors using visual alignment of the various construction elements. As such, the herein described method reduces, if not eliminates the need for complex architectural drawings by encoding the construction sequence directly onto the individual building elements themselves. For purposes of assembly, the herein described method does not require highly specialized labor or extensive training.

Moreover, the herein described methodology can be employed not only on aesthetic structures or applications, but literally any structure formed from bricks or blocks, or other form of individual building element can be constructed. The herein described process is scalable and versatile, extending across various building types and materials and can easily be automated into a workflow. For example, the herein described method can be employed on small scale art installations as well as large-scale architectural structures including residential and commercial buildings or complexes. The method can also be utilized for modular constructions and has potential utility in other prefabricated construction systems.

According to at least one aspect, the herein described method can be employed in software, including a user interface that allows individual users to make real-time adjustments to printed designs, therein enhancing flexibility in modifying images, patterns, or layouts based on project needs.

These and other technical features and advantages will be readily apparent from the following Detailed Description, which should be read in conjunction with the accompanying drawings.

### BRIEF DESCRIPTION OF THE DRAWINGS

FIG. 1 is a photograph depicting three (3) examples of tower structures that are assembled in accordance with aspects of the herein described teachings;

FIG. 2(a), 2(b) and 2(c) are photographs of each of the tower structures depicted in FIG. 1;

FIG. 3 is a flow chart in accordance with an example embodiment in accordance with the present invention;

FIG. 4(a) and 4(b) depict portions of one of the tower structures of FIG., 1 having portions of an imbedded image along with a unique assembly or building code on a facing side of various individual building elements and in accordance with aspects of the herein described teachings;

FIG. 5 is an aerial photograph depicting aspects of an assembly process of one of the tower structures of FIG. 1 and in accordance with aspects of the herein described teachings;

FIG. 6(a), 6(b) and 6(c) are examples of texture patterns for purposes of imprinting on a plurality of individual building elements of the tower structures of FIG. 1 and in accordance with aspects of the herein described teachings;

FIG. 7 is a depiction of the textual patterns of FIG. 6(a), 6(b) and 6(c) being projected onto the rendered tower structure geometries of FIG. 1;

FIG. 8 is an example of an extraction table mapping the coordinates of the superimposed texture pattern(s) onto the plurality of individual building elements of one of the tower structures of FIG. 1 for purposes of creating the unique building codes to be imprinted or otherwise added to each of the individual building elements and in accordance with aspects of the herein described teachings;

FIG. 9 is a deconstructed representation of portions of images of the facing sides of each of the individual building elements of one of the tower structures of FIG. 1;

FIG. 10 is an enlarged view of one of the facing sides of an individual building element as encoded in accordance with aspects of the present teachings;

FIG. 11(a) and 11(b) provide a representation of an alternate structure assembled in accordance with aspects of the present teachings; and

FIG. 12(a)-12(d) are representations of a structure assembled in accordance with another embodiment and in accordance with teachings of the present disclosure.

### DETAILED DESCRIPTION

The following describes a method for construction of a number of various example structures that are created and assembled in accordance with one or more specific embodiments of the present invention. As noted, the structures herein described are merely examples to describe the workings of the inventive method. In addition, and throughout the course of discussion, several terms will be used in order to provide an adequate basis for describing the method. These terms should not be viewed as limiting the overall scope of the invention, except where so specifically indicated. The drawings provided are intended to illustrate salient features of the present invention, but in which the drawings are not necessarily to scale. Accordingly, the drawings should not be used for scalar purposes.

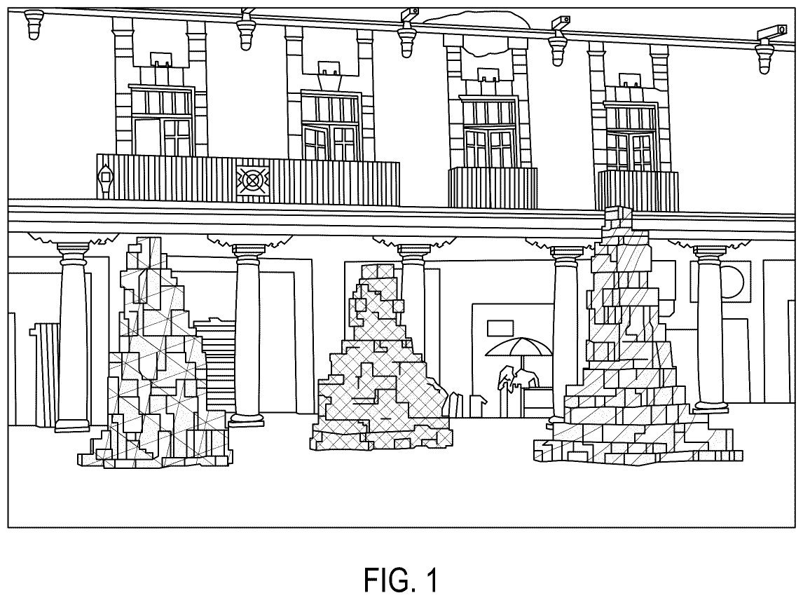

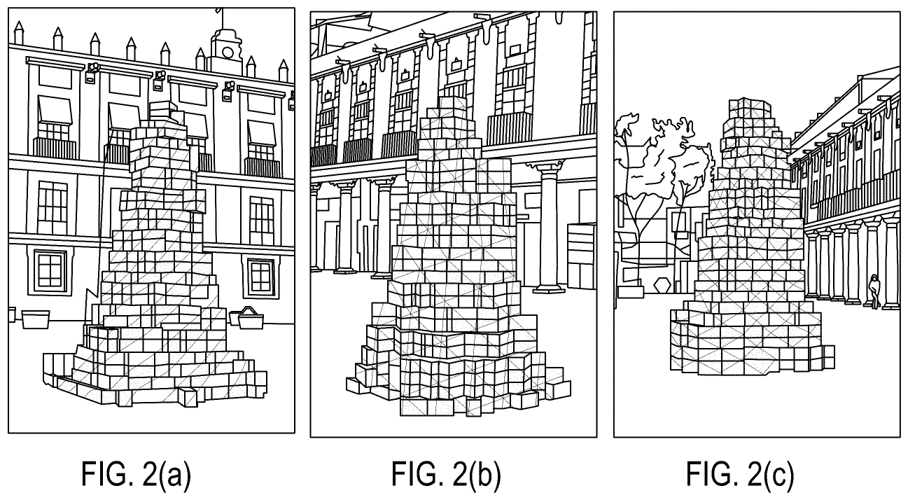

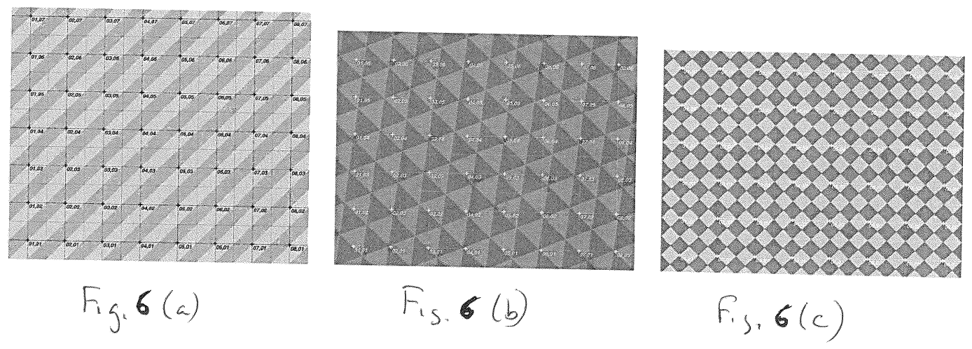

With reference to FIG. 1, there is shown an example in which three (3) tower-like structures are shown, herein referred to as Tower (A), Tower (B), and Tower (C). Individual views of each of the above structures are provided in FIG. 2(a), 2(b) and 2(c), respectively, in which each depicted structure is assembled using a plurality of individual building or construction elements. As discussed herein, each of the Towers (A), (B) and (C) according to this specific embodiment is further defined aesthetically by a different and continuous texture pattern that is imbedded into at least one facing surface, which is best but partially shown in FIG. 6(a), 6(b) and 6(c), respectively. As will be discussed herein, the herein described method is not limited to texture patterns. That is, literally any continuous digital or analog image can be utilized as an aesthetic feature for the structure to be assembled, and as discussed herein as a visual guide for purposes of assembling the structure(s) in addition to specific and unique building or assembly codes, which are also incorporated into each individual building or construction element, as discussed herein.

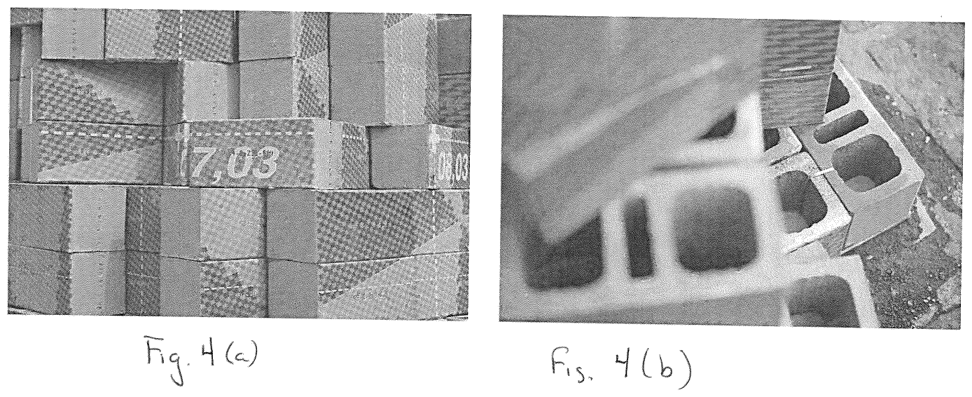

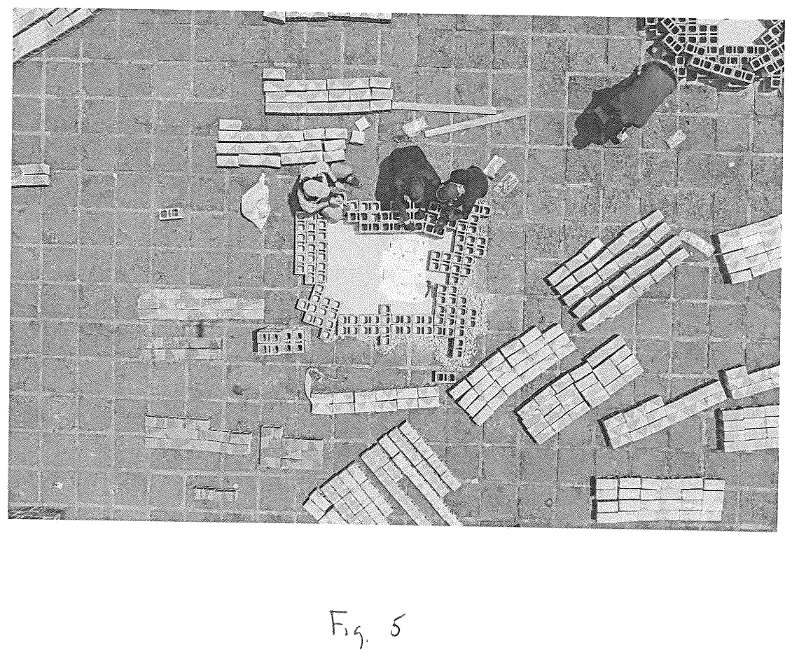

As noted, each of the Towers (A), (B) and (C) are assembled from a plurality of individual building elements. In this specific embodiment, the building elements are bricks, as shown, for example in FIG. 4(a), 4(b) and 5. It will be understood that other types of building elements and materials can be utilized for purposes of this inventive method, such as, but not limited to dimensional lumber, concrete masonry units (CMU), prefabricated concrete panels, prefabricated clay tiles, plywood panels, polycarbonate panels, PET sheets, stone masonry and the like. As will be described in greater detail, at least one facing side of each of the individual building elements according to this specific embodiment (e.g., bricks) are encoded with a portion of one of the texture patterns, such as those shown in FIG. 6(a), 6(b), and 6(c). Each building element is then further tagged with a unique naming or assembly/building code, which allows for cross referencing with other architectural documentation such as, but not limited to architectural plans, sections, elevations, axonometric drawings, 3D models, and renderings. This naming code can be applied in a variety of ways and is not necessarily imbedded, as in the instance of the texture patterns that are presently described herein.

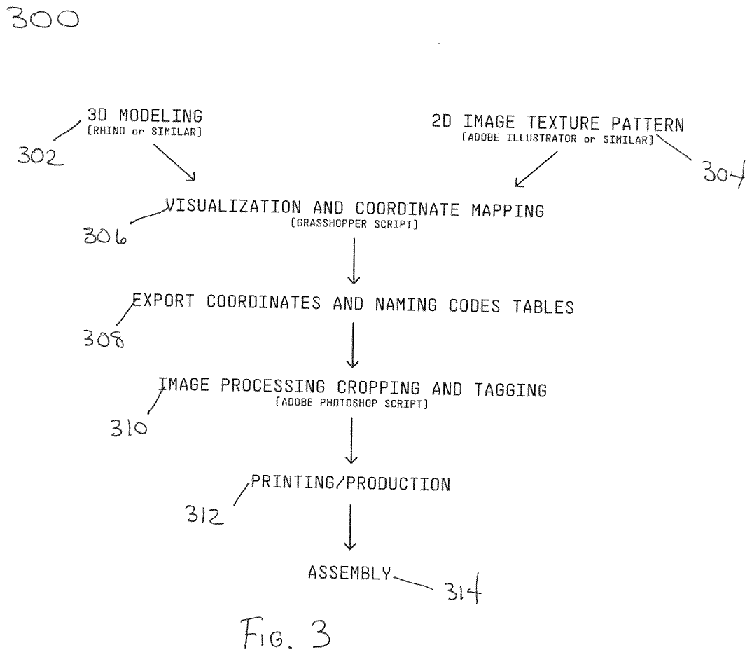

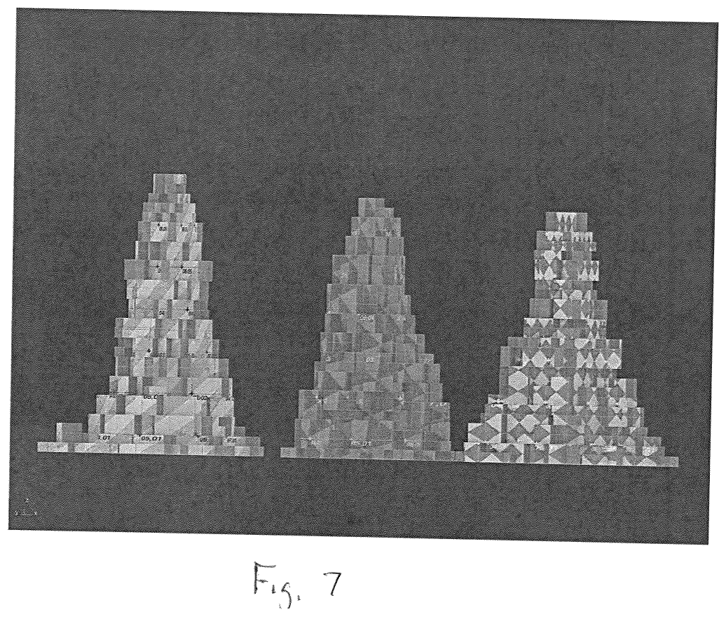

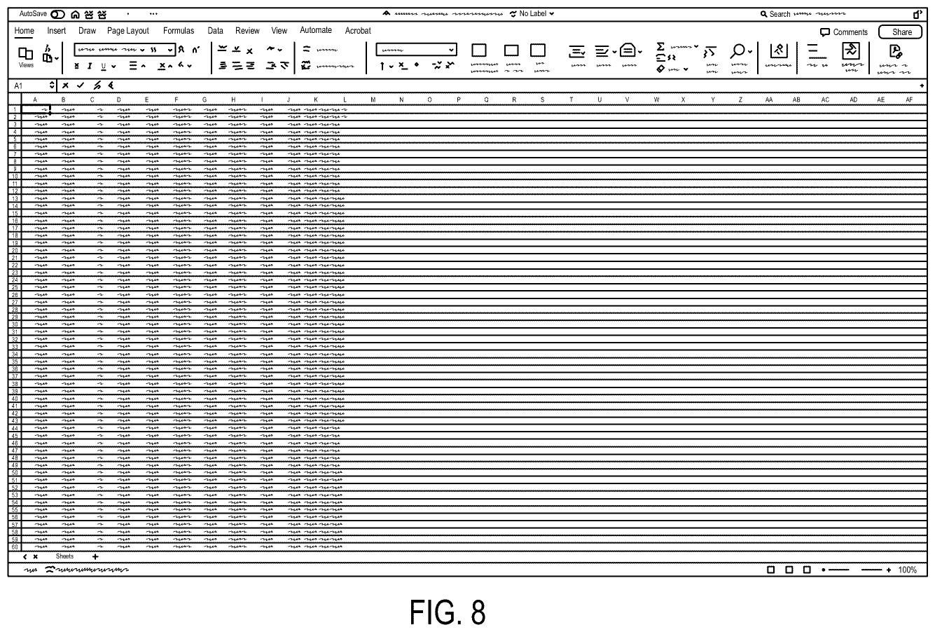

A flow chart of the overall process 300 is provided in FIG. 3. The process according to at least one embodiment is set forth at step 302 by providing a 3-D rendering or model of the structure itself. This can be provided according to at least one version by known 3-D modeling software, such as, for example, Rhino, Autodesk, Blender, or SolidWorks. In addition, per step 304, a 2-D rendering of the continuous digital or analog image (e.g., texture pattern) is further provided using Adobe Illustrator or similar graphics software. At step 306, the 2-D image is superimposed onto the 3-D model of the structure. An example of this superposition is shown in FIG. 7, illustrating the projection of the 2-D image of the texture pattern onto the 3-D models of each of tower structures A, B, and C of FIG. 1. The foregoing is as developed using software that is capable of advanced image manipulation and parametric design, such as Grasshopper or other suitable software. At step 308, coordinates of the resulting merged images are mapped and tabulated for each of the individual building elements of the 3-D model of the structure. An example of the tabular output is tabularly shown in FIG. 8, indicating the coordinates of the image mapping of one of the towers as extracted from the 3-D modeling. According to this specific embodiment, column K of the herein represented table is a code that is assigned to each of the individual building elements and specific coordinates are assigned to each building element relative to their position on the overall digital or analog image (textual pattern), the latter as specified for the individual building elements in columns A-J of the table.

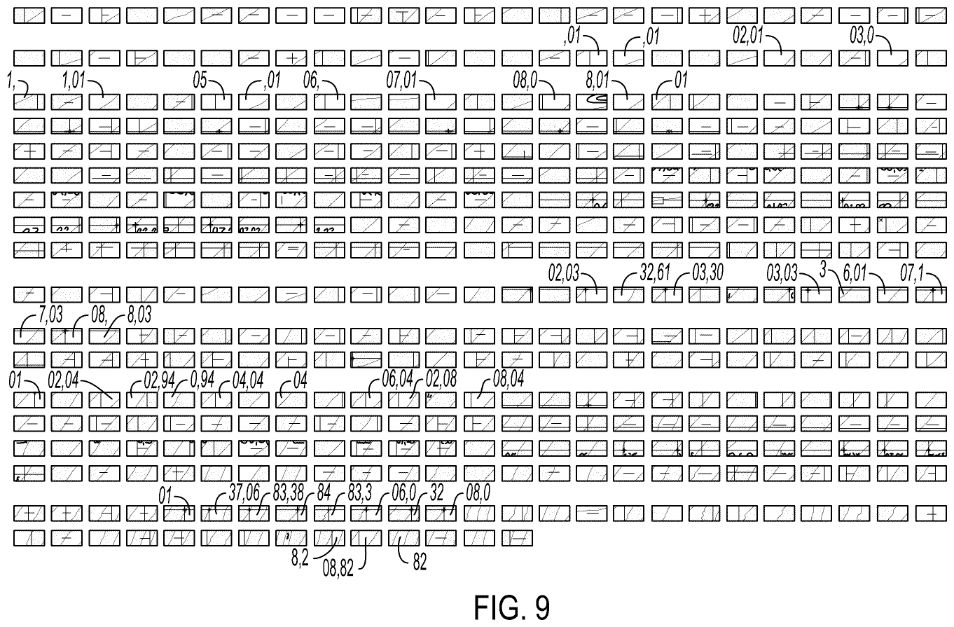

From the resulting table and per step 310, portions of the continuous image are then created. FIG. 9 illustrates output images of each of the facing sides of the individual building elements in a deconstructed form of the overall digital or analog image. In this step, each of the building or construction elements are assigned a specific portion of the image and the naming code. Image processing using Adobe or other software with appropriate cropping is performed to generate a 2-D image for a facing side of each building element, with each of the building elements being printed and produced at step 312 for assembly at step 314. The unique naming or assembly/building code can also be applied on the same facing side of each of the individual building elements or alternatively, the code can be provided on an adjacent non-facing surface thereof.

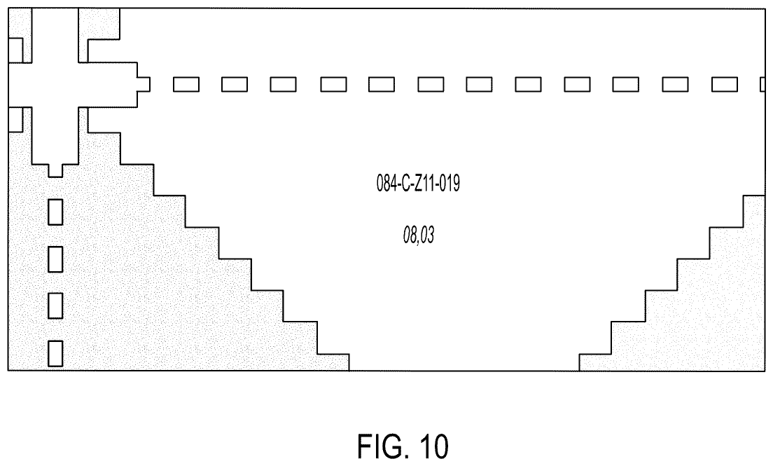

FIG. 10 depicts an example of one a facing surface of a building element that includes the unique code, which according to this example is 084-C-Z11-019. According to this specific embodiment, this naming code includes a project number, followed by building element C, in this instance, which is then followed by a brick course number that begins starting from the bottommost course of the structure to be assembled (course 11 in this instance). Finally, the code according to this embodiment further includes a unique serial number assigned per course (019 in this instance). It will be well understood that the nature and structure of the code assigned to the building elements can vary depending on needs and the form of structure, among other variables. For example, certain structures might not have elements that are easily identified by courses. The naming code(s) may also be provided on a main or primary facing side in some instances while in other instances, the naming code may be printed on another side of the building elements to provide a more refined aesthetic expression..

As noted, various forms of structure can be created using the herein described process. For example, FIG. 11(a) and 11(b) depict another example of a building structure, as well as an illustration of an image that is shown as deconstructed into individual portions for imprinting or coding onto individual building elements. This structure can be assembled using the same method that has been previously described according to the flow chart of FIG. 3, for example.

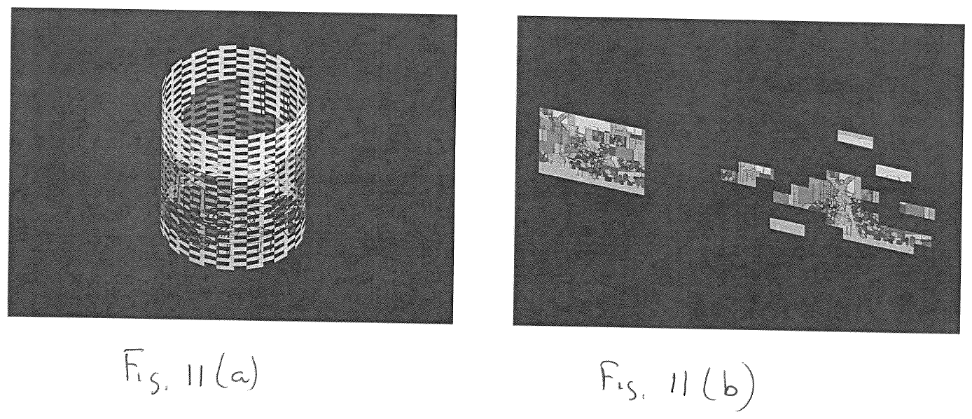

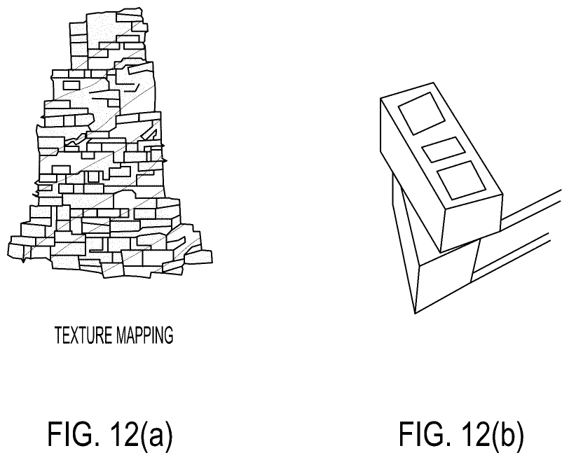

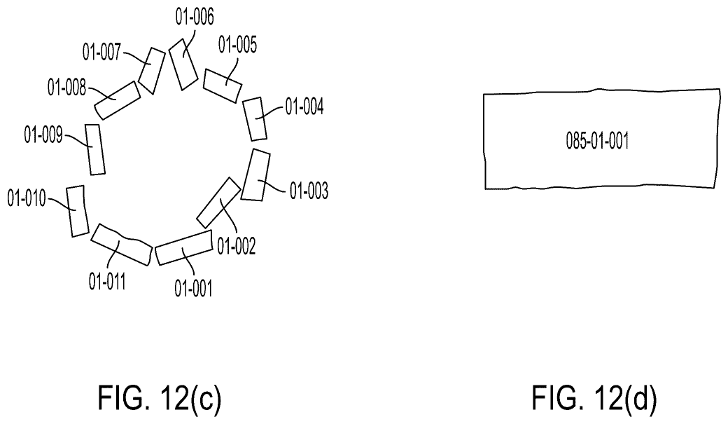

Finally, FIG. 12(a)-12(d) illustrate yet another specific embodiment made in accordance with aspects of the present teachings of a structure assembled from a plurality of individual building elements that is equally applicable to the imprinting and assembly methods described herein.

While the invention has been described in terms of particular variations and illustrative figures, those of ordinary skill in the art will recognize that the invention is not limited to the variations or figures described. In addition, where methods and steps described above indicate certain events occurring in certain order, those of ordinary skill in the art will recognize that the ordering of certain steps may be modified and that such modifications are in accordance with the variations of the invention. Additionally, certain of the steps may be performed concurrently in a parallel process when possible, as well as performed sequentially as described above. Therefore, to the extent there are variations of the invention, which are within the spirit of the disclosure or equivalent to the inventions found in the claims, it is the intent that this patent will cover those variations as well.

To the extent that the claims recite the phrase “at least one of” in reference to a plurality of elements, this is intended to mean at least one or more of the listed elements and is not limited to at least one of each element. For example, “at least one of an element A, element B, and element C,” is intended to indicate element A alone, or element B alone, or element C alone, or any combination thereof. “At least one of element A, element B, and element C” is not intended to be limited to at least one of an element A, at least one of an element B, and at least one of an element C.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed

The corresponding structures, materials, acts, and equivalents of all means or step plus function elements in the claims below, if any, are intended to include any structure, material, or act for performing the function in combination with other claimed elements as specifically claimed. The description set forth herein has been presented for purposes of illustration and description but is not intended to be exhaustive or limited to the form disclosed. Many modifications and variations will be apparent to those of ordinary skill in the art without departing from the scope and spirit of the disclosure. The embodiment was chosen and described in order to best explain the principles of one or more aspects set forth herein and the practical application, and to enable others of ordinary skill in the art to understand one or more aspects as described herein for various embodiments with various modifications as are suited to the particular use contemplated and in accordance with the following appended claims. Additional embodiments include any one of the embodiments described above and described in any and all exhibits and other materials submitted herewith, where one or more of its components, functionalities or structures are interchanged with, replaced by, or augmented by one or more of the components, functionalities or structures of a different embodiment described above.

1. A method for constructing a structure, the method comprising:
i. providing a 3-D model of a structure made up of a plurality of individual building elements;
ii. superimposing a continuous digital or analog image onto the 3-D model of the structure;
iii. mapping and extracting coordinates of the superimposed digital or analog image;
iv. imbedding a portion of the superimposed image onto a facing surface of each of the individual building element along with a unique naming code; and
v. assembling the structure using the unique naming code and the imbedded continuous digital or analog image portions.

2. The method according to claim 1, in which the continuous digital or analog image is an aesthetic image.

3. The method according to claim 1, in which the plurality of individual construction elements are bricks or blocks.

4. The method according to claim 1, in which the unique naming code is placed on a non-facing surface of the individual building elements.

5. A structure comprising a plurality of individual building elements in which a portion of a continuous digital or analog image is imprinted on a common facing surface of each of the individual building elements to serve as a visual building guide for the structure during assembly.

6. The structure according to claim 4, wherein the imprinted digital or analog image is aesthetic to the structure.

7. The structure according to claim 4, in which each of the individual building elements further includes a unique naming code, the naming code being based on mapped coordinates of a 3-D model of the structure having the superimposed digital or analog image.

8. The structure according to claim 7, in which the unique naming code is applied to a non-facing surface of the structure.
